(19) United States
(12) Patent Application Publication
(10) Pub. No.: US 2008/0210306 A1
(43) Pub. Date: Sep. 4, 2008

(54) Integrated surface-machined micro flow controller method and apparatus

(75) Inventors: Jun Xie, Pasadena, CA (US); Jason Shih, Yorba Linda, CA (US); Yu-Chong Tai, Pasadena, CA (US)

Correspondence Address: FOLEY AND LARDNER LLP;SUITE 500, 3000 K STREET NW, WASHINGTON, DC, 20007, US

(73) Assignee: California Institute of Technology

(21) Appl. No.: 11/515,794

(22) Filed: Sep. 6, 2006

Related U.S. Application Data
(63) Continuation of application No. 10/757,030, filed on Jan. 13, 2004, now abandoned.
(60) Provisional application No. 60/440,107, filed on Jan. 15, 2003.

(51) Int. Cl. B81B 3/00; F16K 31/02; F17D 1/00; H01L 41/22; H01L 41/083; F15C 5/00

(52) U.S. Cl. 137/13; 251/129.06; 29/890.124

(57) ABSTRACT

A surface-micromachined mass flow controller (MFC) comprises an electrostatically actuated microvalve integrated with a thermal flow sensor. The microvalve comprises a normally-open diaphragm defining an aperture allowing fluid communication between first and second flow channels. The diaphragm includes a second electrode actuable toward a valve seat including a first electrode. Fabricated utilizing a multilayer Parylene process, the active microvalve and the flow sensor are integrated onto a single chip to perform closed-loop flow control. For flow control, both Pulse Width Modulation (PWM) and actuation voltage adjustment are demonstrated.

### CROSS-REFERENCES TO RELATED APPLICATIONS

This application claims priority to U.S. Provisional No. 60/440,107 filed Jan. 15, 2003, commonly assigned, and which is incorporated by reference herein.

### STATEMENT AS TO RIGHTS TO INVENTIONS MADE UNDER FEDERALLY SPONSORED RESEARCH OR DEVELOPMENT

Work described herein has been supported, in part, by the NSF ERC Center at the California Institute of Technology (Grant No. EEC-9402726) and the DARPA/MTO Bioflips program. The United States Government may therefore have certain rights in the invention.

### BACKGROUND OF THE INVENTION

The present invention relates generally to micro fabrication techniques. More particularly, the invention provides a method and device for manufacturing a fluidic flow control device using a micromachining method and apparatus. Merely by way of example, the invention has been applied to the manufacture of a polymer based mass flow controlling device using electrostatic energy. But it would be recognized that the invention has a much broader range of applicability. For example, the invention can be applied to other applications.

A Micro-Electro-Mechanical System, commonly called MEMS, is generally a batch-fabricated (micro fabricated) system that includes both electrical and mechanical elements. MEMS elements often have characteristic sizes ranging from nanometers to millimeters. MEMS often makes possible certain systems that are smaller, faster, more economical, and energy efficient in some cases. In a general MEMS system, the electrical portion includes integrated circuits, which forms the thinking part, while the electro-mechanical portion works with the thinking part to control functions and perception.

MEMS generally includes micro sensors and actuator devices. Micro sensors often gather outside information such as thermal, biological, optical, gravitational, and others. Actuators often respond to user based information to control their environment. As merely an example, fluidic pumping devices are common examples of MEMS. Such pumping device often rely upon external fluidic drive sources to selectively move fluids through various channel regions. These external drive sources are often cumbersome and lead to inefficiencies. Other pumping devices use drive forces such as electrophoresis. Electrophoresis relies upon a pair of electrodes that are in direct contact with the working fluid. As such, electrophoresis has many limitations. These and other limitations can be found throughout the present specification and more particularly below.

Total integration of many microfluidic devices (e.g., micro pump, valve and flow meter) onto a single chip has been a long sought goal in the microfluidics field. While many devices have been demonstrated using a variety of technologies, incompatibility among different fabrication technologies can create problems during integration. It has been a long-term goal for us to develop a multilayer surface micromachining technology allowing the total integration of various microfluidic devices.

Flow control is an important function of many microfluidic systems. Because of low power consumption and easy implementation, electrostatically actuated microvalves are attractive and have been widely used in flow control. Examples of such electrostatically actuated microvalves are described by P. Dubois et al., “Electrostatically Actuated Gas Microvalve Based on a Ta—Si—N Membrane”, 14th IEEE International Conference on Micro Electro Mechanical Systems pp. 535-538 (2001), incorporated herein by reference for all purposes.

From the above, it is seen that techniques for manufacturing improved MEMS devices is highly desirable.

### BRIEF SUMMARY OF THE INVENTION

According to the present invention, techniques for micro fabrication are provided. More particularly, the invention provides a method and device for manufacturing a fluidic flow control device using a micromachining method and apparatus. Merely by way of example, the invention has been applied to the manufacture of a polymer based mass flow controlling device using electrostatic energy. But it would be recognized that the invention has a much broader range of applicability. For example, the invention can be applied to other applications.

An embodiment of an electrostatic valve device in accordance with the present invention comprises, a substrate, a first fluid channel disposed on the substrate, and a second fluid channel disposed on the substrate. A polymer based diaphragm is coupled between the first fluid channel and the second fluid channel. An orifice is disposed within a portion of the polymer diaphragm, the orifice being adapted to provide fluid communication between the first fluid channel and the second fluid channel. A first electrode is coupled to the substrate, and a second electrode is coupled to the polymer based diaphragm and separated from the first electrode by the first fluid channel. A power source is coupled between the first electrode and the second electrode, the power source being adapted to actuate the diaphragm to block fluid communication between the first fluid channel and the second fluid channel through the orifice.

An embodiment of a method in accordance with the present invention for fabricating a micro fluidic device, comprises, providing a substrate, forming a first electrically conducting layer overlying the substrate, and patterning the first electrode layer to form a first electrode element. A first polymer based layer is formed overlying the first electrode element and the substrate. A first sacrificial layer is formed overlying the first polymer based layer. A second polymer based layer is formed overlying the first sacrificial layer, the second polymer layer defining an aperture. A second electrically conducting layer is formed overlying the first polymer based layer. The second electrode layer is patterned to form a second electrode element associated with the first electrode element, the second electrode layer excluded from the aperture. A third polymer based layer is formed overlying the second electrode element to sandwich the second electrode element between the second polymer based layer and the third polymer based layer, the third polymer based layer also excluded from the aperture. A second sacrificial layer is formed overlying the third polymer based layer and the first sacrificial layer within the aperture. A fourth polymer based layer is formed overlying the second sacrificial layer. The first and second sacrificial layers are released to define respective first and second flow channels in fluid communication through the aperture.

An embodiment of a method in accordance with the present invention for controlling a flow of fluid, comprises, providing a first polymer based layer overlying a first electrode supported by a substrate. A flow channel is defined between the first polymer layer and a diaphragm comprising a second electrode sandwiched between second and third polymer based layers, the second electrode and second and third polymer based layers defining an aperture. A potential difference is selectively applied between the first and second electrodes to draw the second electrode toward the first electrode, thereby causing the diaphragm to seat on the first polymer layer and block a flow of fluid through the aperture.

Numerous benefits are achieved using the present invention over conventional techniques, depending upon the embodiment. In a specific embodiment, the present invention can be implemented using conventional process technologies. Preferably, the present system and method also provide an integrated source for flow control and sensing, which allows for integrated lab on chip applications. Electrostatic actuation in accordance with embodiments of the present invention also offers the advantages of ease of implementation in a microscale system, and efficient power consumption, the latter being a particularly important characteristic of portable applications. Depending upon the embodiment, one or more of these benefits may be achieved. These and other benefits are provided throughout the present specification and more particularly below.

Various additional objects, features and advantages of the present invention can be more fully appreciated with reference to the detailed description and accompanying drawings that follow.

### BRIEF DESCRIPTION OF THE DRAWINGS

FIG. 1 shows a photographic plan view of one embodiment of chip containing a flow controlling device in accordance with the present invention.

FIGS. 2A-B show simplified cross-sectional views illustrating operation of one embodiment of a flow control device in accordance with the present invention.

FIGS. 3A-D shows simplified cross-sectional views of one embodiment of a process flow for fabricating a flow control device in accordance with the present invention.

FIG. 4 shows a micrograph of a flow controlling device in accordance with the present invention.

FIG. 5 plots voltage drop versus flow rate illustrating the flow sensor characteristics for air flow through one embodiment of a device in accordance with the present invention.

FIG. 6 plots voltage drop versus flow rate illustrating the tlow sensor characteristics for water flow through one embodiment of a device in accordance with the present invention.

FIG. 7 plots voltage versus time, showing measurement of thermal time constant for one embodiment of a device in accordance with the present invention.

FIG. 8 plots flow rate versus actuation voltage for devices in accordance with the present invention having different pressures within the flow channel.

FIG. 9A is a simplified timing diagram of the control signal for one embodiment of the present invention.

FIG. 9B is a simplified diagram showing the voltage of the resulting actuation signal resulting from the control signal of FIG. 9A.

FIG. 10 plots voltage change versus time, illustrating flow sensor output according to a control signal of a specific frequency.

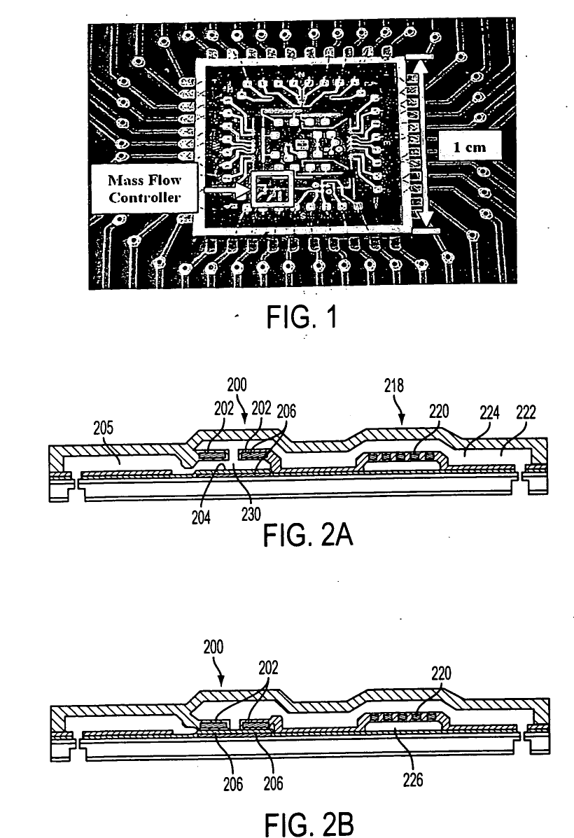

FIG. 1I plots flow rate versus duty cycle, illustrating flow control for one operational mode of a device in accordance with the present invention.

### DETAILED DESCRIPTION OF THE INVENTION

According to the present invention, techniques for micro fabrication are provided. More particularly, the invention provides a method and device for manufacturing a fluidic flow control device using a micromachining method and apparatus. Merely by way of example, the invention has been applied to the manufacture of a polymer based mass flow controller using electrostatic energy. But it would be recognized that the invention has a much broader range of applicability. For example, the invention can be applied to other applications.

FIG. 1 shows a photograph of one embodiment of a fabricated micro flow controller in accordance with the present invention, formed on a PCB-mounted microfluidic chip. Unlike conventional microvalve designs, the electrostatically actuated microvalve is entirely surface micromachined using Parylene technology. Moreover, with the versatility of the multilayer process, a thermal based flow sensor is also integrated with the microvalve for flow measurement and closed-loop feedback flow control.

FIGS. 2A-B show simplified cross-sectional views illustrating the design of the micro mass flow controller and its operation principle. The design takes advantage of the versatility and flexibility of the multilayer Parylene process.

Specifically, the microvalve 200 is realized by using electrostatic force to actuate a circular Parylene membrane 202. FIG. 2A shows a simplified cross-section of the micro flow controller in a valve open state.

An applied voltage moves the membrane 202 in contact with the valve seat 204 and closes the fluid pathway 205. FIG. 2B shows the micro flow controller in a valve closed state. Comparison of FIGS. 2A-B indicates that this microvalve is a normally open device.

All the electrodes 206 are encapsulated by Parylene to achieve electrical insulation. Experimentally, Yao et al., “Dielectric Charging Effects on Parylene Electrostatic Actuators”, The 15th IEEE International Conference on Micro Electro Mechanical Systems pp. 614-617 (2002), incorporated by reference for all purposes herein, have found that the breakdown field of Parylene is about 200V/μm, which allows good electrical insulation with just a thin Parylene layer. In one embodiment in accordance with the present invention, the dimensions of the moving membrane (200 μm diameter, 2 μm thick) are carefully chosen so the diaphragm will not be so flexible as to stick to the bottom during drying, nor so rigid as resist bending during operation.

The flow sensor 218 is thermally based, an approach described previously by Wu et al., “MEMS flow sensors for nano-fluidic applications,” Sensors and Actuators A: Physical, 89 (1-2) pp. 152-158 (2001), incorporated by reference herein for all purposes. In CC (Constant Current) mode, the flow rate is related to the voltage drop across the resistive heater 220 due to heat transfer between the heater and fluid 222 inside the channel 224. To improve the sensitivity, a thermal isolation cavity 226 is created underneath the flow sensor using the same sacrificial layer that creates the gap 230 between the two electrodes 206 of the valve. The heater 220 uses the same metal layer as the top electrode of the valve.

A method for fabricating a micro fluidic flow controlling device can be outlined as follows:

1. Provide a support substrate including backside and front side, e.g., silicon wafer;
2. Form an oxide layer (or other dielectric material layer or multi-layers) overlying the surfaces of the substrate;
3. Form a photolithographic pattern overlying the oxide layer;
4. Define openings in the oxide layer using the photolithographic pattern to pattern the backside of the substrate;
5. Deposit first conducting layer overlying the front side of the substrate;
6. Pattern first conducting layer to form electrode structures;
7. Form first polymer based layer overlying the electrode structures;
8. Form first sacrificial layer overlying the first polymer based layer;
9. Form second polymer based layer overlying the first sacrificial layer;
10. Pattern second polymer based layer;
11. Form and pattern second conducting layer defining second electrode and heater elements overlying the second polymer based layer;
12. Form third polymer based layer overlying the second conducting layer;
13. Form second sacrificial layer overlying the third polymer based layer;
14. Form fourth polymer based layer overlying the second sacrificial layer;
15. Open backside regions to the sacrificial layers;
16. Release sacrificial layers; and
17. Perform other steps, as desired.

The above sequence of steps provide a method of fabricating a beam structure of polymer based material using micromachining techniques. As shown, the method uses a combination of front side patterning and backside patterning according to a specific embodiment. The method forms a pump device that is composed of multiple polymer based materials. Preferably, the polymer based material is a Parylene material such as Parylene-C, but can be others. Additionally, certain steps may be combined, one or more steps may be added, and one or more steps may be removed, depending upon the embodiment. The sequence of the steps is changed in certain embodiments. Further details of the present method can be found throughout the present specification and more particularly below.

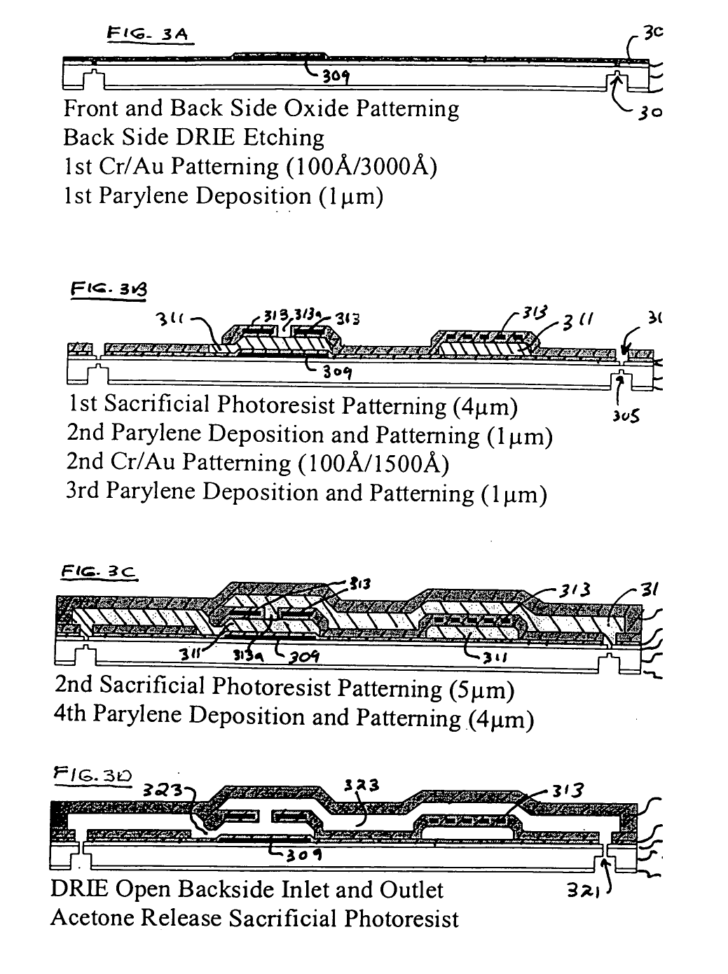

One specific fabrication process is outlined in connection with FIGS. 3A-D, which are simplified cross-sectional view diagrams illustrating a method for fabricating a fluid regulating device according to an embodiment of the present invention. These diagrams are merely illustrations, which should not unduly limit the scope of the claims herein. One of ordinary skill in the art would recognize many variations, alternatives, and modifications.

As shown in FIG. 3A, the method begins by providing a support substrate structure 300, e.g., silicon wafer, glass substrate, which has a surface and a thickness defined underlying the surface. The structure also includes an oxide layer 303 overlying the surface of the substrate. The surface includes front side and backside. Although such oxide layer has been illustrated, such layer or layers may also include nitrides, a combination of oxide and nitride, and others, which serve as a hard mask to protect surfaces of the substrate. Preferably, the layer is formed using wet oxidation techniques such as steam oxidation and/or wet dipping, as well as others. Of course, one of ordinary skill in the art would recognize many variations, modifications, and alternatives.

The method forms a photolithographic pattern overlying the oxide layer. The pattern is often formed by coating the surface with a photosensitive material, which is exposed and then developed. Openings are formed in the photosensitive material. Such openings correspond to trench regions or recessed regions to be formed in the substrate. Etching techniques are often used to form openings in the oxide layer to expose substrate region, which will be subjected to reactive ion etching processes or other directional etching processes. Preferably, deep reactive ion etching, commonly called DRIE, is used to form openings 305, as illustrated by FIG. 3A, to define recessed regions or trenches, including sides and lower portions. The recessed regions extend toward the front surface of the substrate.

The method forms an electrode layer 309 overlying the surface of the oxide, as shown. The electrode layer is often a conductive material, such as a single layer or multiple layers. As merely an example, the conductive material can be Au that is deposited. Other materials such as aluminum, platinum, titanium, and doped polysilicon can also be used.

The electrode layer is often provided to a predetermined thickness. Preferably, the Cr/Au is deposited to a thickness of about 100/3000 Å. A 3000 Å gold layer is evaporated on the front side as the ground electrode of the valve and wire bonding pads.

The electrode layer is patterned to form discrete electrode regions. The electrode layer has been or will be coupled to a voltage potential once the device has been completed.

The method forms a layer of polymer based material 307 overlying the oxide layer and the electrode. The polymer based material grows on the exposed surfaces of the substrate.

Preferably, the polymer based material is Parylene, which is a commercial name for polymers that belong to a chemical family called poly-para-Xylylene. Parylene is often deposited using gaseous monomers. Such monomers are polymerized and deposited on the substrate, including the trench region, as a pinhole-free and stress-free solid film with selected physical, thermal, electrical, barrier, and biocompatible properties. As shown, Parylene is a conformal protective polymer coating material that conforms to surfaces of the substrate. Parylene exhibits dielectric strength, high surface and volume resistivities, and electrical properties that may be independent of temperature. It also provides a substantially conformal, pinhole-free coating that is corrosion resistance and provides dielectric protection. Before going to the next step, we shall briefly discuss deposition techniques of Parylene using a vacuum chemical vapor deposition process.

Parylene is often applied at a molecular level by a vacuum deposition process at ambient temperature or other temperatures. The vacuum deposition process includes a vaporizer, a pyrolysis, and a deposition chamber. The deposition chamber is often coupled to cold trap, which is coupled to vacuum pump. The vacuum pump maintains vacuum in the chamber. Parylene can be applied at room temperature with certain vacuum deposition equipment that permits control of coating rate and thickness. The deposition process takes place at the molecular level as the chemical, in dimer form, is converted under vacuum and heat to dimeric gas, pyrolized to cleave the dimer, and deposited as a clear polymer film. Depending upon the embodiment, Parylene may come in one of a variety of forms such as Parylene C, Parylene N, and Parylene D, which correspond to three dimer variations. Each of the dimer variations could be suited to the requirements of a specific embodiment. Preferably, Parylene C is desirable. Further details of the deposition apparatus and characteristics of Parylene can be found at the website of Conformal-Coating.com. Of course, there can also be other variations, modifications, and alternatives.

In the specific embodiment of a fabrication process shown in FIGS. 1A-D, adhesion between the first Parylene layer and the underlying oxide and electrode is promoted by first applying adhesion promoter A174 from Specialty Coating Systems of Indianapolis, Ind.

The 1-μm Parylene CVD deposition seals the electrode. This layer also serves as a buffer to improve adhesion between the successive Parylene layer and the substrate. This is because the presence of sacrificial photoresist subsequently formed, prevents the use of the adhesion promoter later in the process.

Referring to now FIG. 3B, the method next forms a sacrificial layer 311 overlying the first polymer-based layer. The sacrificial layer is preferably any material that can be easily removed at a later process. Preferably, the sacrificial layer is a polymer based material that can dissolve. Such material can be photoresist or other like material. The sacrificial layer will occupy a portion of the fluid flow channel region that is closed-off during operation of the present device. In the specific embodiment of FIG. 3B, a 4-μm photoresist sacrificial layer will defines the gap between the two electrodes of the valve, and thermal isolation cavity of the flow sensor.

Referring still to FIG. 3B, the method then forms a sandwiched structure over the first sacrificial layer. This structure comprises second conducting layer 313 patterned into a second electrode and heater elements, sandwiched between second and third polymer based layers. In the specific embodiment shown in FIG. 3B, the top electrode and heater are formed by a 100/1500 Å chrome/gold bilayer which is encapsulated between two 1-μm-thick Parylene layers.

During this phase of the process flow, the second conducting layer is patterned to define an upper electrode having an aperture 313a therein, and also to define separate portions of the heater element. As illustrated in FIG. 2B, fluid flows through this aperture when the valve structure is in its normally-open state.

Certain techniques may be employed to enhance adhesion between the deposited parylene and the underlying material, and also to enhance between the conducting material and the underlying Parylene. For example, oxygen plasma cleaning and roughening may be performed before each Parylene deposition to improve the adhesion, and may also be performed prior to the deposition of the Cr/Au over the Parylene.

An opening 315 is then formed overlying the substrate within the polymer based materials. The opening will be used to release an overlying sacrificial layer, which will be applied for the fluid flow channel.

Referring now to FIG. 3C, a second sacrificial material 317 is deposited over the sandwiched structure. As shown, this sacrificial layer extends to opening 315, which will be used to introduce solvent to release the sacrificial layer. In the specific embodiment shown in FIG. 3A-D, the second sacrificial material comprises a 5 μm-thick layer of photoresist,

Overlying the second sacrificial layer is a fourth layer of polymer based material 319. Preferably, the polymer based material is Parylene, which is a commercial name for polymers that belong to a chemical family called poly-para-Xylylene. As described above, Parylene is often deposited using gaseous monomers. Such monomers are polymerized and deposited on the substrate, including the trench region, as a pinhole-free and stress-free solid film with selected physical, thermal, electrical, barrier, and biocompatible properties. In the specific embodiment shown in FIG. 3D, the fourth polymer based material comprises a 4 μm-thick layer of Parylene.

The method then releases the sacrificial layers, as illustrated by FIG. 3D. Here, an etching process removes material from the backside of the substrate to form an opening 321, which extends through the substrate and exposes the sacrificial material. Once the sacrificial material has been exposed, solvents and/or etchants are used to dissolve the sacrificial layers and remove them from the flow channel region 323.

In one embodiment, acetone was used to dissolve sacrificial material comprising photoresist. Experiments, however, showed that prolonged Acetone soaking can result in delamination between Parylene layers. So as soon as most of photoresist is dissolved, the chips were transferred to Isopropyl Alcohol for further cleaning.

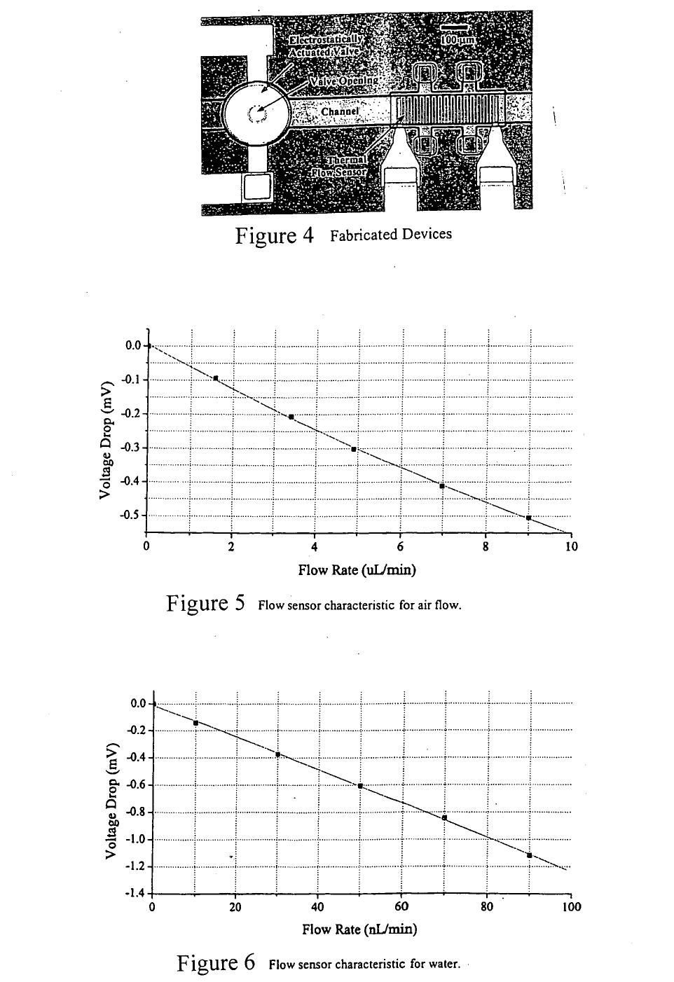

FIG. 4 shows a micrograph of the fabricated device.

Further details of the present device including additional fabrication techniques can be found throughout the present specification and more particularly below.

Testing and Results

Flow Sensor

The flow measurement setup is similar to that of Wu et al., “MEMS flow sensors for nano-fluidic applications,” Sensors and Actuators A: Physical, 89 (1-2) pp. 152-158 (2001), incorporated by reference herein for all purposes For airflow calibration, a constant pressure is applied to the inlet and a precision 10 μL pipette is connected at the outlet. The volumetric flow rate is measured by the traveling speed of a bead of water in the pipette. For water flow calibration, a syringe pump is used to deliver a precise flow rate. The thermal sensor is operated in constant current mode. The ambient in the room is typically about 23° C. and the fluctuation can be around +/−1° C. To compensate for the effect of ambient or substrate temperature variations, outputs of two sensors with identical geometries are measured simultaneously. One of them is the actual flow sensor and the other is a compensation sensor located nearby. The difference between the outputs of these two sensors is taken as the final output for flow measurement. The temperature coefficient of resistance, α; of the gold heater is measured to be 0.33%/° C.

Sensitivity Sv is defined as the ratio between output voltage change and flow rate. The relationship between temperature-to-flow ratio, TCR and sensitivity is expressed by Equation (1) below:

$${S}_{V} = {V}_{0} α \frac{Δ T}{Δ Q} = {V}_{0} α {S}_{T} \qquad ( 1 )$$

FIG. 5 shows the voltage output as a function of airflow rate. A 4 mA bias current is applied, which corresponds to a heater temperature of 6.3° C. above the ambient. Sensitivity Sv is 55 μV/(μL/min) and temperature-to-flow ratio is 0.033° C./(μL/min). Output voltage is measured with a HP34401A multimeter at a rate of 1 Hz. The resolution of the voltage measurements are 10 μV. So the resolution of the flow rate measurements are roughly 0.2 μL/min.

FIG. 6 shows the flow measurement calibration for water. The bias current is again 4 mA. The sensitivity is 12.2 μV/(nL/min) and the temperature-to-flow ratio is 0.0073° C./(nL/min). Water flow calibration proves to be more difficult. Due to the relatively large off-chip testing setup compared to the small flow rate, stabilization of flow takes a long time (>10 min). This demonstrates the importance and advantage of on-chip flow measurement.

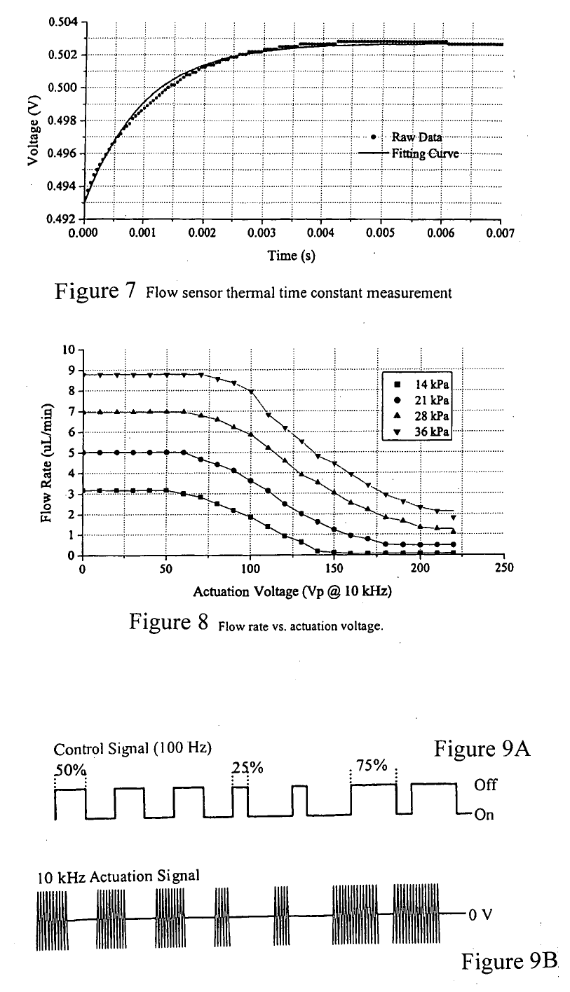

To study the dynamic response of the thermal flow sensor, the thermal time constant of the heater is measured. After switching on the 4 mA bias current, there is a nearly instantaneous jump to a voltage corresponding to the zero-bias resistance. The voltage, or resistance, change as a function of time, due to the heating, is given in FIG. 7. The thermal time constant is measured to be about 1.0 ms. Data was collected using a HP54645 digital oscilloscope.

Electrostatic Actuation

To characterize the electrostatic valve, a voltage is applied between the two electrodes to actuate the valve membrane. The pull-in voltage is measured to be around 130 VDC. During the testing, we observe that after many actuations, the actuation strength attenuates. In addition, we observed a shift in pull-in voltage to as high as 180 VDC. Dielectric charging is the suspected cause of this shift.

To solve this problem, an AC actuation voltage is used, as suggested by, described also by van der Wijngaart et al., “A High-Stroke, High-Pressure Electrostatic Actuator for Valve Applications”, Sensors and Actuators A, 100 pp. 264-271 (2002), incorporated by reference herein for all purposes. A sinusoidal voltage is applied to the top electrode while the bottom electrode is grounded. A high frequency of 10 kHz is chosen so there will be no oscillations of the valve at the actuation signal frequency. Using AC voltage, the pull-in voltage is about 110 Vpeak (+/−110 V). The actuation strength remains stable in successive actuations. AC actuation is clearly better for our flow controller.

When the valve is actuated with water as the liquid, electrolysis problems may be observed when using either DC or 10 kHz AC actuation. This occurs even though both electrodes are encapsulated with Parylene, which should provide electrical insulation.

With water as the fluid, the valve membrane can be actuated using a DC voltage of around 20-40 V, but bubbles are generated almost immediately. Due to the rapid volume expansion of the bubbles, damage to the valve membrane may result. This electrolysis problem may prevent the valve structure from operating with water. However, the structure has been demonstrated to control the flow of liquids exhibiting a high resistance to electrolysis, such as Fluorinert.

Micro Flow Controller

In testing of the flow control capability of the system, two operation modes are investigated and compared. One mode is to adjust the actuation voltage amplitude. The other uses Pulse Width Modulation (PWM) as suggested by the DuBois et al. reference.

In both cases, based on our calibrations, flow sensor output is used to measure the flow rate as we adjust the actuation parameters. Constant pressure is applied to the channel inlet to induce flow. Valve actuation signal frequency is kept at 10 kHz.

FIG. 8 shows the relationship between output flow rate and actuation voltage amplitude. It is clear that as the pressure increases, the voltage needs to increase to stop the flow. When the pressure is higher than 28 kPa, the valve cannot be fully closed with voltages up to 220 Vpeak. Due to the positive feedback characteristic of electrostatic actuation, the linear region of the control curve is small.

Since electrostatic actuation exhibits the pull-in phenomenon, it would be more beneficial to operate the valve in an on/off binary mode instead of the analog mode that is shown in FIG. 8. To control flow rate, PWM is utilized. One requirement for PWM operation is that the valve has to switch fast enough so a relatively smooth flow is seen downstream.

FIGS. 9A-B illustrate the control scheme. A pulsed modulation signal is applied to a solid state relay at 100 Hz. The relay controls the valve by switching the 10 kHz actuation voltage.

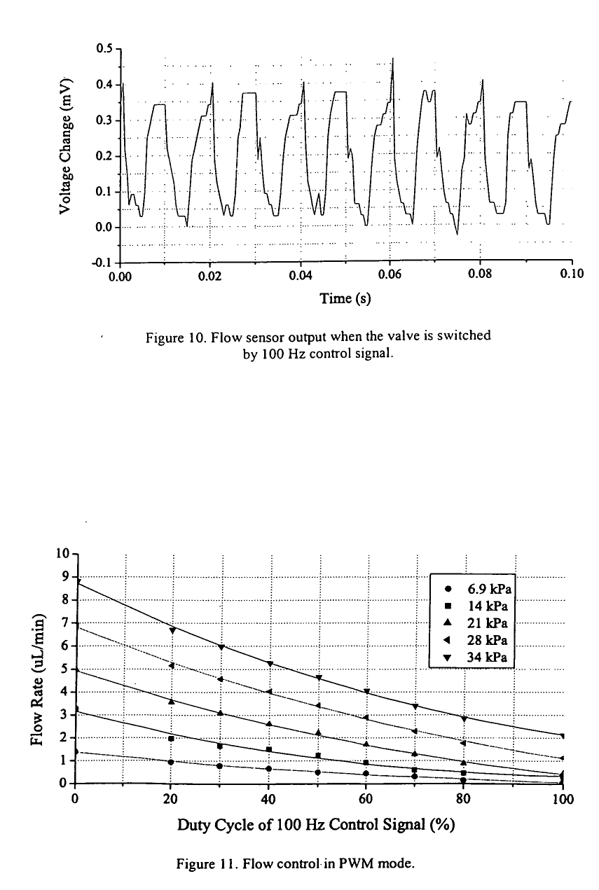

The flow sensor output in FIG. 10 shows system response to a 100 Hz control signal. Actuation voltage in FIG. 10 is 160 Vpeak and applied pressure is 34 kPa. System time constant is estimated to be around 1.5 ms and the valve actuation speed is likely on the order of 1 ms as well.

FIG. 11 shows the flow control results using PWM mode. The actuation signal is 200 Vpeak at 10 kHz. The pulse control signal is 100 Hz. For pressures lower than 21 kPa, the valve can be nearly completely closed. From 20% to 80% duty cycle, the control is quite linear. Non-linearity at both low (<20%) and high (>80%) duty cycles is caused by the fact that pulse durations are approaching the valve speed limit. Thus PWM operation becomes less ideal at both ends. Even with this non-linearity, PWM control is still more linear than the control achieved by adjusting actuation voltage.

In conclusion, a flow controller on a chip comprising an electrostatically actuated microvalve integrated with a thermal flow sensor, has been developed. Together, these elements function as a micro mass flow controller. Fabrication of such a system is enabled by a multilayer Parylene process. Testing results demonstrate effectiveness of the design and flow control capability of the system for small airflow in the range of several μl/min.

One specific embodiment of such a mass flow controller exhibits a flow sensor sensitivity of about 55 μV/(μL/min) for airflow and about 12.2 μV/(nL/min) for water. The valve is actuated with a 10 kHz AC signal and an applied pressure of 21 kPa can be sealed with an actuation voltage of 200 Vₚₑₐₖ (+200 V). For flow control, both Pulse Width Modulation (PWM) and actuation voltage adjustment are demonstrated. PWM shows better performance in terms of controllability and linearity.

It is understood that the examples and embodiments described herein are for illustrative purposes only and that various modifications or changes in light thereof will be suggested to persons skilled in the art and are to be included within the spirit and purview of this application and scope of the appended claims. As merely an example, the Parylene material has been deposited according to certain embodiments, other material can be injection molded such as thermoplastics and the like. Of course, there can be other variations, modifications, and alternatives.

What is claimed is:

1. An electrostatic valve device comprising:
a substrate;
a first fluid channel disposed on the substrate;
a second fluid channel disposed on the substrate;
a polymer based diaphragm coupled between the first fluid channel and the second fluid channel;
an orifice disposed within a portion of the polymer diaphragm, the orifice being adapted to provide fluid communication between the first fluid channel and the second fluid channel;
a first electrode coupled to the substrate;
a second electrode coupled to the polymer based diaphragm and separated from the first electrode by the first fluid channel; and
a power source coupled between the first electrode and the second electrode, the power source being adapted to actuate the diaphragm to block fluid communication between the first fluid channel and the second fluid channel through the orifice.

2. The device of claim 1 wherein the first fluid channel and the second fluid channel contain liquid.

3. The device of claim 1 wherein the first fluid channel and the second fluid channel contain gas.

4. The device of claim 1 wherein at least one of the first and second fluid channels is characterized by a height of less than 5 micron.

5. The device of claim 1 wherein both the first and second fluid channels are characterized by a height of equal or larger than 5 micron.

6. The device of claim 1 wherein first fluid channel has a height that is different from a height of the second fluid channel.

7. The device of claim 1 wherein the polymer based diaphragm has a diameter ranging from 10 to 1000 micron.

8. The device of claim 1 wherein the polymer diaphragm is characterized by a diameter larger than 1000 micron.

9. The device of claim 1 wherein the polymer diaphragm is characterized by a thickness ranging from 0.1 to 10 micron.

10. The device of claim 1 wherein the polymer based diaphragm is characterized by a thickness of larger than 10 micron.

11. The device of claim 1 wherein the second electrode is embedded within the polymer based diaphragm.

12. The device of claim 1 wherein the substrate is made of a material selected from silicon or glass.

13. The device of claim 1 wherein the polymer based diaphragm comprises a material selected from parylene, polyimide, or silicone.

14. The device of claim 1 wherein at least one of the first and second electrodes comprises a conducting material selected from the group consisting of chrome, gold, aluminum, titanium, platinum, and doped polysilicon.

15. The device of claim 1 further comprising a flow sensor coupled to one of the first and the second flow channels, the flow sensor configured to provide flow measurement information to the valve to achieve feedback flow control.

16. A method for fabricating a micro fluidic device, the method comprising:
providing a substrate;
forming a first electrically conducting layer overlying the substrate;
patterning the first electrode layer to form a first electrode element;
forming a first polymer based layer overlying the first electrode element and the substrate;
forming a first sacrificial layer overlying the first polymer based layer;
forming a second polymer based layer overlying the first sacrificial layer, the second polymer layer defining an aperture;
forming a second electrically conducting layer overlying the first polymer based layer;
patterning the second electrode layer to form a second electrode element associated with the first electrode element, the second electrode layer excluded from the aperture;
forming a third polymer based layer overlying the second electrode element to sandwich the second electrode element between the second polymer based layer and the third polymer based layer, the third polymer based layer also excluded from the aperture;
forming a second sacrificial layer overlying the third polymer based layer and the first sacrificial layer within the aperture;
forming a fourth polymer based layer overlying the second sacrificial layer; and
releasing the first and second sacrificial layers to define respective first and second flow channels in fluid communication through the aperture.

17. The method of claim 16 wherein forming the first and second sacrificial layers comprises patterning photoresist.

18. The method of claim 17 wherein releasing the first and second sacrificial layers comprises exposing the first and second sacrificial layers to acetone.

19. The method of claim 18 further comprising exposing the first and second sacrificial layers to isopropyl alcohol once the first and second flow channels have been substantially defined.

20. The method of claim 16 wherein the first polymer based layer, the second polymer based layer, and third polymer based layer are provided using chemical vapor deposition of Parylene.

21. The method of claim 16 wherein:
patterning the second electrode layer also forms a heating element, the heating element in thermal communication with one of the first and the second flow channel; and
releasing the first sacrificial layer defines a cavity providing thermal isolation of the heating element.

22. A method of controlling a flow of fluid comprising:
providing a first polymer based layer overlying a first electrode supported by a substrate;
defining a flow channel between the first polymer layer and a diaphragm comprising a second electrode sandwiched between second and third polymer based layers, the second electrode and second and third polymer based layers defining an aperture; and
selectively applying a potential difference between the first and second electrodes to draw the second electrode toward the first electrode, thereby causing the diaphragm to seat on the first polymer layer and block a flow of fluid through the aperture.

23. The method of claim 22 further comprising:
defining a thermal isolation cavity between the first polymer layer and a heating element sandwiched between the second and third polymer layers and in thermal communication with the flow channel;
detecting a voltage change in the heating element reflecting a velocity of fluid flow through the flow channel; and
changing the potential difference based on the voltage change.

24. The method of claim 22 wherein defining the flow channel comprises:
patterning a first sacrificial layer over the first polymer layer;
forming a second sacrificial layer in the aperture over a first sacrificial layer; and
removing the first and second sacrificial layers.

25. The method of claim 24 wherein:
patterning a first and second sacrificial layers comprises patterning photoresist; and
removing the first and second sacrificial layers comprises introducing acetone.

26. The method of claim 22 wherein the first polymer based layer, the second polymer based layer, and the third polymer based layer are provided using chemical vapor deposition of Parylene.
